(19) United States
(12) Patent Application Publication
(10) Pub. No.: US 2009/0221139 A1
(43) Pub. Date: Sep. 3, 2009

(54) Method of producing semiconductor device

(75) Inventor: Toru Yoshie, Tokyo (JP)

Correspondence Address: KUBOTERA & ASSOCIATES, LLC, 200 Daingerfield Road, Suite 202, Alexandria, VA, 22314, US

(73) Assignee: Oki Semiconductor Co., Ltd.

(21) Appl. No.: 12/379,341

(22) Filed: Feb. 19, 2009

(30) Foreign Application Priority Data
Feb. 29, 2008 (JP) 2008-049653

(51) Int. Cl. H01L 21/443

(52) U.S. Cl. 438/590; 257/E21.478; 257/E21.497

(57) ABSTRACT

A method of producing a semiconductor device includes the steps of: forming an oxide film on a silicon carbide substrate; forming a gate electrode layer on the oxide film; patterning the gate electrode layer to form a gate electrode; and processing thermally the gate electrode layer or the gate electrode under an oxidation environment. Further, the gate electrode layer or the gate electrode is thermally processed under the oxidation environment at a temperature between 750° C. and 900° C.

### BACKGROUND OF THE INVENTION AND RELATED ART STATEMENT

The present invention relates to a method of producing a semiconductor device. More specifically, the present invention relates to a method of producing a semiconductor device using a silicon carbide substrate.

A semiconductor device using a silicon carbide (SiC) crystal has been known to have high voltage resistance and be capable of operating at a high temperature, as compared with a semiconductor device using a silicon (Si) crystal. The silicon carbide crystal contains carbon atoms. Accordingly, an inter-atomic distance decreases to increase a bonding between atoms, thereby increasing a band gap of a semiconductor more than double. As a result, the semiconductor device using the silicon carbide (SiC) crystal has resistance up to an electric field more than double and maintains a semiconductor property at a high temperature.

When an oxide film is formed on a silicon carbide substrate, the silicon carbide substrate is processed under an oxidation environment such as dry oxidation using oxygen (O₂) or wet oxidation using H₂O (refer to Patent Reference) Patent Reference: Japanese Patent Publication No. 2007-201343

When an oxide film is formed on the silicon carbide substrate, especially a 3C-silicon carbide substrate, an interfacial level and fixed electric charges are created in an interface between the silicon carbide substrate and the oxide film. On the other hand, when a 4H-silicon carbide substrate is used, although an optimal oxidation condition depends on a surface thereof, the dry oxidation is effective on an Si surface at 1,300° C. together with a post annealing in Ar and an annealing in H₂. Further, an oxidation in N₂O is effective at 1,350° C. The wet oxidation is effective on a C surface at 1,000° C.

It is found that the 3C-silicon carbide substrate has a property similar to the C surface of the 4H-silicon carbide substrate. That is, with the dry oxidation, the fixed electric charges increases, so that the wet oxidation is effective. In general, after a gate electrode is formed on the oxide film using poly-silicon, a thermal processing is applied to activate the gate electrode. During the thermal processing to activate the gate electrode, carbon tends to pile up in an interface between the silicon carbide substrate and a gate oxide film. Accordingly, the interfacial level increases between the silicon carbide substrate and the gate oxide film due to the piled up carbon atoms. That is, positive fixed electric charges are generated, thereby increasing an absolute value of a flat band voltage and shifting a threshold value of a semiconductor device to a negative side.

When the oxide film (the gate oxide film) is formed through the wet oxidation as described above, the threshold value of a semiconductor device tends to shift to the negative side. When the threshold value of the semiconductor device shifts to the negative side to a small extent, it is possible to correct the threshold value back to a positive side. However, when the threshold value of the semiconductor device tends to shift to the negative side to a large extent, it is difficult to correct the threshold value. Accordingly, when a gate voltage is not applied, a current flows through the semiconductor device, thereby making it difficult to produce a so-called normally-off semiconductor device.

In view of the problems described above, an object of the present invention is to provide a method of producing a semiconductor device capable of solving the problems of the conventional method of producing the semiconductor device. In the invention, it is possible to minimize the shift of the threshold value to the negative side even when a thermal processing is applied to activate a gate electrode layer or a gate electrode.

Further objects and advantages of the invention will be apparent from the following description of the invention.

### SUMMARY OF THE INVENTION

In order to attain the objects described above, according to an aspect of the present invention, a method of producing a semiconductor device includes the steps of: forming an oxide film on a silicon carbide substrate; forming a gate electrode layer on the oxide film; patterning the gate electrode layer to form a gate electrode; and processing thermally the gate electrode layer or the gate electrode under an oxidation environment. Further, the gate electrode layer or the gate electrode is thermally processed under the oxidation environment at a temperature between 750° C. and 900° C.

In the present invention, even when the thermal processing is applied to activate the gate electrode layer or the gate electrode, it is possible to minimize a shift of a threshold value to a negative side.

### BRIEF DESCRIPTION OF THE DRAWINGS

FIGS. 1(A) to 1(D) are schematic sectional views No. 1 showing a method of producing a semiconductor device according to a first embodiment of the present invention;

FIG. 2 is a schematic sectional view No. 2 showing the method of producing the semiconductor device according to the first embodiment of the present invention;

FIGS. 3(A) to 3(D) are schematic sectional views No. 1 showing a method of producing a semiconductor device according to a second embodiment of the present invention;

FIGS. 4(A) and 4(B) are schematic sectional views No. 2 showing the method of producing the semiconductor device according to the second embodiment of the present invention; and

FIG. 5 is a graph showing a CV property of the semiconductor device produced with the method according to the present invention and a semiconductor device produced with a conventional method.

### DETAILED DESCRIPTION OF PREFERRED EMBODIMENTS

According to the present invention, a method of producing a semiconductor device includes the steps of: forming an oxide film on a silicon carbide substrate; forming a gate electrode layer on the oxide film; patterning the gate electrode layer to form a gate electrode; and processing thermally the gate electrode layer or the gate electrode under an oxidation environment.

In general, a thermal processing is applied a gate electrode to activate the gate electrode. During the thermal processing to activate the gate electrode, carbon atoms in an oxide film tend to pile up in an interface between a silicon carbide substrate and the oxide film. The piled up carbon atoms behave like positive fixed electric charges, thereby increasing an interfacial level and a flat band voltage to a negative side. As a result, a threshold value of a semiconductor device significantly shifts to a negative side, thereby deteriorating a switching property of a semiconductor device.

In the present invention, the gate electrode layer and the gate electrode are thermally processed under the oxidation environment. Accordingly, it is possible to reduce carbon atoms piling up in the interface as carbon dioxide gas or carbon monoxide gas. As a result, it is possible to reduce the fixed electric charges and the interfacial level of the interface between the silicon carbide substrate and the oxide film, thereby reducing an absolute value of the flat band voltage. That is, it is possible to restrict the threshold value from shifting to the negative side, thereby largely improving the switching property of the semiconductor device.

Further, in the embodiment, after the gate electrode layer is patterned to form the gate electrode, the gate electrode is thermally processed under the oxidation environment. As a result, damage in an edge portion of the gate electrode is restored through the re-oxidation, thereby improving voltage resistance yield of the semiconductor device.

Hereunder, preferred embodiments of the present invention will be explained with reference to the accompanying drawings. In the drawings, shapes, sizes, and positional relations of components are schematically for understanding the present invention, and the present invention is not limited thereto. In the following description, a specific material, a specific condition, or a numerical condition is used as an example, and the present invention is not limited thereto.

### First Embodiment

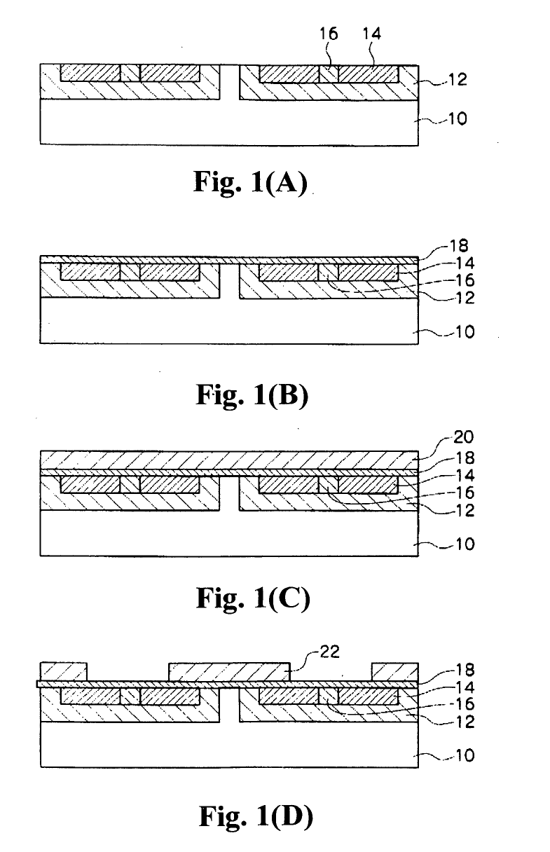

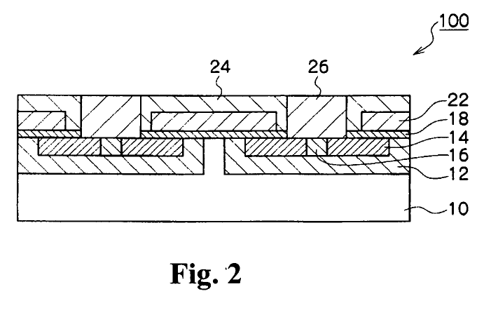

A first embodiment of the present invention will be explained. FIGS. 1(A) to 1(D) are schematic sectional views No. 1 showing a method of producing a semiconductor device according to the first embodiment of the present invention. FIG. 2 is a schematic sectional view No. 2 showing the method of producing the semiconductor device according to the first embodiment of the present invention.

As shown in FIG. 1(A), impurities are implanted into a surface layer of an N-type silicon carbide substrate 10 to form a P-type diffusion layer 12, an N+ diffusion layer 14, and a P+ diffusion layer 16. More specifically, aluminum (Al) ions are implanted to form the P-type diffusion layer 12 and the P+ diffusion layer 16, and phosphorous ions are implanted to form the N+ diffusion layer 14. The impurities are implanted with a well-known ion implantation method.

In the next step, the silicon carbide substrate 10 is processed under an Ar environment or vacuum less than 1×10⁻⁵ Pa at a temperature between 1,500° C. and 1,700° C. for a few minutes to 60 minutes to activate the impurities and restore crystallinity of the silicon carbide substrate 10.

In the next step, as shown in FIG. 1(B), a gate oxide film 18 is formed on a surface of the silicon carbide substrate 10. It is preferred that the silicon carbide substrate 10 is thermally oxidized to form the gate oxide film 18. As far as the oxidation is performed under the oxidation environment, the method thereof is not limited. It is preferred that the oxidation is performed under an environment of a gas mixture of H₂ and O₂ for preventing carbon atoms from piling up near an interface between the gate oxide film 18 and the silicon carbide substrate 10.

Further, it is preferred that the oxidation is performed at a temperature between 1,100° C. and 1,200° C. for 30 minutes in consideration of the piling up of carbon atoms. It is preferred that the gas mixture contains H₂ and O₂ at a ratio between 1:2 to 1:100. When the ratio is less than 1:2, there is an explosion risk. When the ratio is greater than 1:100, an environment becomes near dry due to an excessive amount of O₂. As a result, carbon atoms tend to pile up near the interface between the gate oxide film 18 and the silicon-carbide substrate 10, and fixed electric charges and an interfacial level increase, thereby shifting a flat band voltage to a negative side and greatly shifting a threshold value of the semiconductor device to a negative side. Note that the gate oxide film 18 has a thickness between 40 nm and 100 nm.

In the next step, as shown in FIG. 1(C), a gate electrode layer 20 containing phosphorous is formed. More specifically, SiH₄ gas and PH₄ gas flow at a ratio of about 10:1 at a temperature between 500° C. and 600° C. When it is necessary to reduce a resistivity of the gate electrode layer 20, a WSi having a thickness between 100 nm and 300 nm is formed on the gate electrode layer 20. In the next step, as shown in FIG. 1(D), the gate electrode layer 20 is patterned through well-known photolithography and etching to form a gate electrode 22.

In the next step, a thermal processing is performed to activate the gate electrode 22. It is preferred that the thermal processing is performed under the oxidation environment at a temperature between 750° C. and 900° C. The gate electrode layer 20 is formed of poly-silicon, WSi, TiSi, NiSi, CoSi, and the likes. Especially when the gate electrode layer 20 is formed of poly-silicon, poly-silicon is crystallized and activated through the thermal processing.

In the embodiment, when the thermal processing is performed at a temperature less than 750° C., it is difficult to activate the gate electrode 22. When the thermal processing is performed at a temperature greater than 900° C., the gate electrode 22 tends to be oxidized and a large amount of carbon atoms tend to pile up. Accordingly, it is preferred that the thermal processing is performed at a temperature between 750° C. and 800° C., so that a temperature is maintained between 750° C. and 800° C. during the thermal processing.

In the embodiment, it is preferred that the thermal processing is performed for a period of time between 10 minutes and 30 minutes. When the thermal processing is performed for a period of time less than 10 minutes, it is difficult to activate the gate electrode 22. When the thermal processing is performed for a period of time greater than 30 minutes, the gate electrode 22 tends to be oxidized and a large amount of carbon atoms tend to pile up.

In the embodiment, the thermal processing is performed under the oxidation environment, so that carbon atoms piling up in the interface between the silicon carbide substrate 10 and the gate oxide film 18 are removed as carbon oxide gas, thereby reducing the fixed electric charges and the interfacial level. It is preferred that at least one of O₂, N₂O, NO₂, and H₂O is contained in the oxidation environment.

In the embodiment, the thermal processing may be performed to activate the gate electrode 22 after the gate electrode 22 is formed through the photolithography and etching, or the thermal processing may be performed to activate the gate electrode layer 20 before the gate electrode layer 20 is patterned through the photolithography and etching. In both cases, it is possible to remove carbon atoms piling up in the interface between the silicon carbide substrate 10 and the gate oxide film 18 with oxygen in the oxidation environment.

In the next step, as shown in FIG. 2, the gate oxide film 18 exposed is etched and removed to form an interlayer insulation film 24. Then, a contact hole 26 of Al or Cu and a wiring portion (not shown) are formed, thereby producing the semiconductor device.

In the embodiment, the silicon carbide substrate 10 is used to produce the semiconductor device from viewpoints of high voltage resistance and high temperature operation. Silicon carbide may include 2H—SiC, 3C—SiC, 4H—SiC, 6H—SiC, 8H—SiC, 10H—SiC, 15R—SiC, and the likes according to the Ramsdell notation. According to the Ramsdell notation, the first number represents the number of Si—C unit layers contained in one cycle in the lamination direction (c-axis direction). The second alphabets represent cubic (C), hexagonal (H), and rhombohedron (R).

Among various forms of silicon carbide, 4H—SiC, 6H—SiC, and 15R—SiC are produced at a temperature greater than 2,000° C., and 3C—SiC can be produced at a temperature less than 1,800° C. 3C—SiC has a highest electron travel speed in crystal (a saturated electron speed is 2.7 times higher than that of Si), and a crystal structure (cubic) similar to that of conventional Si. Accordingly, it is preferred to use 3C—SiC, so that it is possible to produce a semiconductor device with a high speed, a high efficiency, and a fine arrangement at a low temperature. It is possible to produce the 3C—SiC substrate through hetero-epitaxial growth using an Si substrate, thereby making it possible to easily increase a diameter of the substrate, and reducing substrate manufacturing cost as compared with other methods.

### Second Embodiment

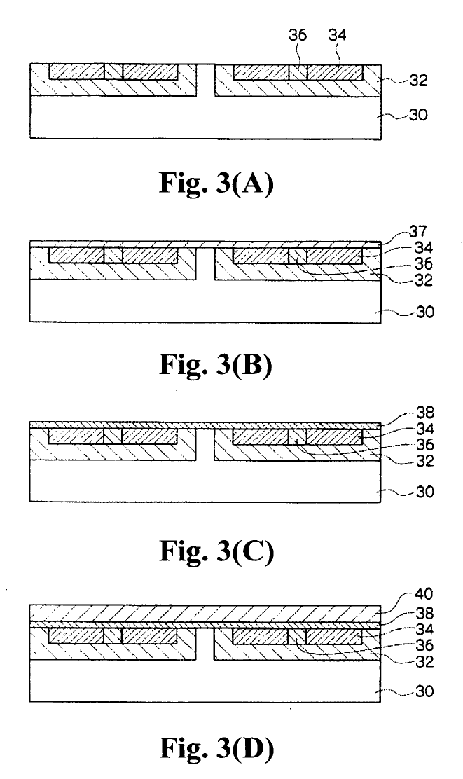

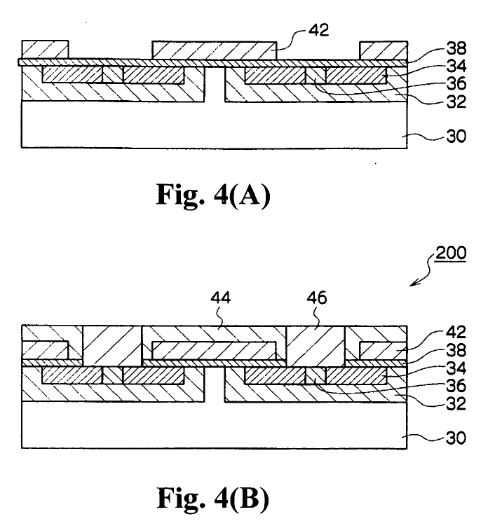

A second embodiment of the present invention will be explained next. FIGS. 3(A) to 3(D) are schematic sectional views No. 1 showing a method of producing a semiconductor device according to the second embodiment of the present invention. FIGS. 4(A) and 4(B) are schematic sectional views No. 2 showing the method of producing the semiconductor device according to the second embodiment of the present invention.

As shown in FIG. 3(A), similar to FIG. 1(A) in the first embodiment, a P-type diffusion layer 32, an N+ diffusion layer 34, and a P+ diffusion layer 36 are formed in a surface layer of an N-type silicon carbide substrate 30.

In the next step, as shown in FIG. 3(B), an amorphous silicon layer 37 is formed on the silicon carbide substrate 30 under an environment of SiH₄ or SiH₂Cl₂ at a temperature between 500° C. and 520° C. When the temperature is less than 500° C., it takes long time to form the amorphous silicon layer 37. When the temperature is greater than 520° C., a poly-silicon is formed. The amorphous silicon layer 37 has a thickness between one third and half of that of a gate oxide film 38, so that the silicon carbide substrate 30 is not oxidized.

In the next step, as shown in FIG. 3(C), after the amorphous silicon layer 37 is formed, the gate oxide film 38 is formed through thermal oxidation. The thermal oxidation is performed under conditions similar to those for forming the gate oxide film 18 in the first embodiment except that a temperature is set between 750° C. and 900° C. It is preferred that the gate oxide film 38 is formed with a chemical vapor deposition (CVD) method at a temperature between 500° C. and 900° C. In the thermal oxidation, as described above, the amorphous silicon layer 37 is formed and thermally oxidized.

In the next steps, as shown in FIGS. 3(D), 4(A) and 4(B), similar to those in FIGS. 1(D) and 2, after a gate electrode layer 40 is formed, a gate electrode 42 is formed through photolithography and etching. Then, an interlayer insulation film 44 and a contact hole 46 are formed, thereby producing the semiconductor device.

As described above, in the method of producing the semiconductor device according to the second embodiment of the present invention, instead of the silicon carbide substrate 30, the amorphous silicon layer 30 is oxidized to form the gate oxide film 38 at the temperature not oxidizing the silicon carbide substrate 30. Accordingly, it is possible to obtain the gate oxide film 38 with reduced fixed electric charges and the interfacial level without an influence of carbon atoms in the silicon carbide substrate 30.

Further, after the gate oxide film 38 is formed, similar to the first embodiment, the gate electrode 42 is activated at the temperature between 500° C. and 900° C. under the oxidation environment. Accordingly, it is possible to form the gate oxide film 38 with a good property without piling up carbon atoms near the interface between the silicon carbide substrate 30 and the gate oxide film 38. Further, the CVD film with good capability of covering a step portion is oxidized to form the gate oxide film 38. Accordingly, it is possible to reduce defects in the silicon carbide substrate 30, and minimize deterioration in voltage resistance of the gate oxide film 38 due to a step portion and the likes.

### Third Embodiment

A third embodiment of the present invention will be explained next. In a method of producing the semiconductor device according to the third embodiment of the present invention, the amorphous silicon layer is not oxidized, and the gate oxide film is directly formed on the silicon carbide substrate with the CVD method.

More specifically, the gate oxide film is formed under a gas mixture of tetraethoxysilane (TEOS) and oxygen at a low pressure and a temperature between 600° C. and 900° C. The gas mixture may be SiH₄ and Si₂H₆ instead of tetraethoxysilane, and N₂O, NO₂, and H₂O instead of oxygen. When the gate oxide film is formed at a temperature greater than 900° C., carbon atoms in the silicon carbide substrate tend to pile up. When the gate oxide film is formed at a temperature greater than 600° C., it is difficult to decompose the Si raw material.

As described above, in the embodiment, the gate oxide film is directly formed on the silicon carbide substrate with the CVD method. Accordingly, it is possible to minimize deterioration in voltage resistance of the gate oxide film due to a step portion and the likes. Further, it is not necessary to add the oxidation step, thereby reducing the manufacturing steps and manufacturing time.

An experiment was conducted for evaluating a CV property of the semiconductor devices produced with the methods of the invention. In the experiment, three Examples No. 1 to No. 3 and two Comparative Examples No. 1 and No. 2 were produced for the evaluation.

### Example No. 1

Nitrogen atoms were doped in a 3C—SiC substrate at a concentration of 1×10¹⁶/cm³ to prepare an N-type substrate. Then, the N-type substrate was processed under H₂O environment (wet environment) at a temperature increase decrease rate of 30° C./min and a temperature of 1,170° C. for 25 minutes, so that the 3C—SiC substrate was thermally oxidized to form the gate oxide film. In the next step, SiH₄ gas and PH₄ gas flowed in a chamber at a temperature of 550° C. to form the poly-silicon layer. Then, the thermal processing was performed under O₂ environment at a temperature of 800° C. for 20 minutes to activate the gate electrode. At last, the gate electrode pattern is formed through photolithography and etching, thereby producing a MOS capacitor.

### Example No. 2

Instead of the thermal oxidation of Example No. 1, the gate oxide film was formed through the following process, thereby producing a MOS capacitor with the method similar to that of Example No. 1.

The amorphous silicon layer was formed with the CVD method under SiH₄ environment at a temperature of 510° C. Then, the amorphous silicon layer was thermally oxidized under H₂O environment (wet environment) at a temperature increase decrease rate of 30° C./min and a temperature of 850° C. for 30 minutes to form the gate oxide film.

### Example No. 3

Instead of thermal oxidizing the amorphous silicon layer of Example No. 2, the gate oxide film was formed through the following process, thereby producing a MOS capacitor with the method similar to that of Example No. 1.

The silicon carbide substrate with the diffusion layer formed therein was processed with the CVD method in a gas mixture of tetraethoxysilane and oxygen at a ratio of 2:1, a pressure of 1 Pa, and a temperature of 700° C. for 60 minutes, thereby forming the gate oxide film.

### Comparative Example No. 1

Instead of the thermal oxidation under oxygen gas of Example No. 1 after the gate electrode was formed, the thermal oxidation was performed under N₂ gas, thereby producing a MOS capacitor with the method similar to that of Example No. 1.

### Comparative Example No. 2

The gate electrode was formed aluminum (Al) and the thermal processing was not performed after the gate electrode was formed, thereby producing a MOS capacitor with the method similar to that of Example No. 1.

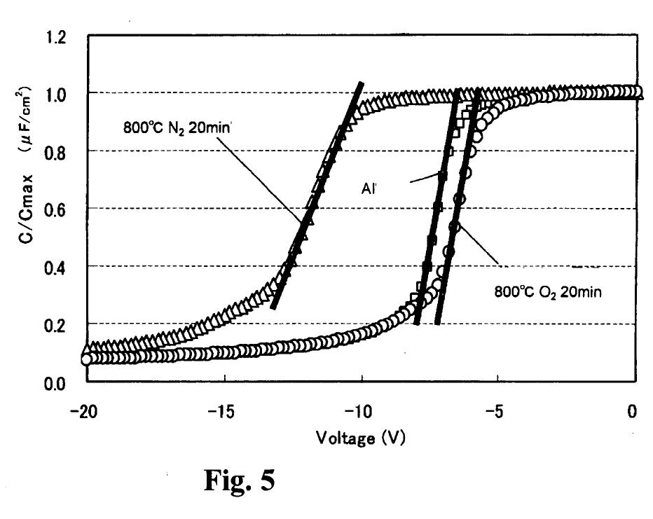

In evaluating the CV property of the semiconductor devices, i.e., Examples No. 1 to No. 3 and Comparative Example No. 1 and No. 2, LCR meter 4284B (a product of HP, currently Agilent Technologies) was used to measure a gate voltage and a capacitance (μF/cm²) thereof, so that a shift of a hysteresis toward a negative side and a slope thereof were evaluated. FIG. 5 is a graph showing the CV property of the semiconductor device produced with the method according to the present invention and the semiconductor device produced with the conventional method.

As shown in FIG. 5, the semiconductor devices, i.e., Examples No. 1 to No. 3, produced with the methods according to the present invention show the CV property having the reduced shift toward the negative side. Further, as compared with the Al gate electrode of Comparative Example No. 2, in which it is not necessary to perform the thermal processing to activate the gate electrode, the shift toward the negative side is reduced in Examples No. 1 to No. 3.

Further, the CV property of Examples No. 1 to No. 3 indicated with a solid line has a steep slope, as compared with the CV property of Comparable Examples No. 1 and No. 2. Accordingly, in the semiconductor devices, i.e., Examples No. 1 to No. 3, produced with the methods according to the present invention, a concentration of carbon atoms piling up near the interface between the silicon carbide substrate and the gate oxide film is reduced, thereby preventing the fixed electric charges and the interfacial level from increasing.

The disclosure of Japanese Patent Application No. 2008-049653, filed on Feb. 29, 2008, is incorporated in the application by reference.

While the invention has been explained with reference to the specific embodiments of the invention, the explanation is illustrative and the invention is limited only by the appended claims.

What is claimed is:

1. A method of producing a semiconductor device, comprising the steps of:
forming an oxide film on a silicon carbide substrate;
forming a gate electrode layer on the oxide film;
patterning the gate electrode layer to form a gate electrode; and
processing thermally the gate electrode layer or the gate electrode under an oxidation environment.

2. The method of producing the semiconductor device according to claim 1, wherein, in the step of processing thermally the gate electrode layer or the gate electrode under the oxidation environment, said gate electrode layer or said gate electrode are thermally processed under the oxidation environment at a temperature between 750° C. and 900° C.

3. The method of producing the semiconductor device according to claim 1, wherein, in the step of processing thermally the gate electrode layer or the gate electrode under the oxidation environment, said gate electrode layer or said gate electrode are thermally processed under the oxidation environment containing at least one of O₂, N₂O, NO₂, and H₂O.

4. The method of producing the semiconductor device according to claim 1, wherein, in the step of forming the oxide film on the silicon carbide substrate, said oxide film is formed through thermally oxidizing the silicon carbide substrate.

5. The method of producing the semiconductor device according to claim 1, wherein, in the step of forming the oxide film on the silicon carbide substrate, said oxide film is formed through a chemical vapor deposition method at a temperature between 500° C. and 900° C.

6. The method of producing the semiconductor device according to claim 1, further comprising the steps of forming an amorphous silicon layer and thermally oxidizing the amorphous silicon layer to form the oxide film.

7. The method of producing the semiconductor device according to claim 1, wherein, in the step of forming the oxide film on the silicon carbide substrate, said oxide film is formed under an environment of a gas mixture of tetraethoxysilane and oxygen.

8. The method of producing the semiconductor device according to claim 1, wherein, in the step of forming the oxide film on the silicon carbide substrate, said silicon carbide substrate is formed of a cubic crystal silicon carbide.
